(19) United States
(12) Patent Application Publication
(10) Pub. No.: US 2015/0096617 A1
(43) Pub. Date: Apr. 9, 2015

(54) COMPOUND SEMICONDUCTOR SOLAR BATTERY

(71) Applicant: TDK CORPORATION, Tokyo (JP)

(72) Inventors: Masato Kurihara, Tokyo (JP); Yasuhiro Aida, Tokyo (JP)

(21) Appl. No.: 14/381,418

(22) PCT Filed: Feb. 28, 2013
(86) PCT No.: PCT/JP2013/055270

§ 371 Date: Aug. 27, 2014

(30) Foreign Application Priority Data
Feb. 28, 2012 (JP) 2012-041945

(51) Int. Cl. H01L 31/032; H01L 31/0296; H01L 31/0749

(52) U.S. Cl. CPC H01L 31/0322; H01L 31/0749; H01L 31/0296
USPC 136/260

(57) ABSTRACT

A compound semiconductor solar battery according to the present invention includes a substrate; a back electrode disposed on the substrate; a p-type compound semiconductor light absorbing layer disposed on the back electrode; an n-type compound semiconductor buffer layer disposed on the p-type compound semiconductor light absorbing layer; and a transparent electrode disposed on the n-type compound semiconductor buffer layer. The p-type compound semiconductor light absorbing layer has a cross sectional structure including, in a thickness direction, a portion only of a single particle and a portion of a plurality of piled particles. In the portion of a plurality of piled particles, the particles in contact with the back electrode have a ratio y1 of Ga/(In+Ga), and the particles in contact with the n-type compound semiconductor buffer layer have a ratio y2 of Ga/(In+Ga), where y1>y2.

### TECHNICAL FIELD

The present invention relates to a compound semiconductor solar battery.

### BACKGROUND ART

Crystal silicon-type solar batteries and the compound thin film-type solar batteries of CdS-type or CIGS (CIS)-type, in which a part of CuInSe₂ is substituted by Ga, the latter batteries seeing increasingly widespread use in recent years, are designed for solar power generation systems for outdoor installation. While these systems provide high conversion efficiency in the outdoor environment where sufficient illuminance can be obtained, the conversion efficiency significantly decreases as the illuminance is lowered. Thus, these systems are not suitable for low illuminance utilization, such as in an area with a low probability of fine weather or indoors. Meanwhile, for uses such as portable electronic devices utilized in low illuminance environments such as indoors, amorphous silicon thin film-type solar batteries have been conventionally used. Although inferior to the crystal silicon type or the compound thin film type in outdoor use, the amorphous silicon thin film-type solar batteries have a small rate of change in conversion efficiency with respect to illuminance decreases, and allow the use of a flexible substrate.

As portable devices are provided with increasingly more sophisticated functionality, their power consumption is increasing. Thus, there is a need for a solar battery having high conversion efficiency even at low illuminance.

### CITATION LIST

### Non-Patent Documents

Non-Patent Document 1: Weak Light Performance and Spectral Response of Different Solar Cell Types, Proc. 20th European Photovoltaic Solar Energy Conference and Exhibition, Barcelona, Spain, 6-10 Jun. 2005.

Non-Patent Document 2: J. Appl. Pys. 99, 01496 (2006).

### SUMMARY OF THE INVENTION

### Problem to be Solved by the Invention

The CIGS (CIS) type, which is of the same thin film type and which enables the use of a flexible substrate, exhibits a higher conversion efficiency than the amorphous silicon type in outdoor use. Thus, it would, be promising if the conversion efficiency cart be maintained at low illuminance of 10 mW/cm² or less.

In Non-Patent Document 1, the relationship between illuminance and conversion efficiency is compared among amorphous silicon, GaAS, single crystal silicon, polycrystal silicon, and CIS-type solar batteries. The document shows that the conversion efficiency decreases particularly in the crystal silicon type and the CIS type at low illuminance corresponding to cloudy weather or indoors.

In the CIGS-type solar battery, those in which the growth of crystal particles in the CIGS layer has progressed are utilized in order to increase conversion efficiency, and there is a number of grain, boundaries parallel with the thickness direction and through the CIGS layer. In addition, there is a heterogenous phase with low resistivity at the grain boundaries and the shunt resistance is lowered, so that the generation efficiency is not sufficient at low illuminance.

In Non-Patent Document 2, a technology tor improving low illuminance characteristics by varying the Cu. concentration in CIGS (Ga/(In+Ga)=0.3) is disclosed. By towering from 21.5 or 23.3 at %, at which high efficiency is obtained outdoors, to 18 at %, grain boundaries are increased and shunt resistance is increased, thereby increasing the open-circuit voltage at low illuminance and the fill factor. However, the short-circuit current at high illuminance is low, so that the conversion efficiency is not sufficient

The present invention was made in view of the above problems. The purpose of the present invention is to provide a CIGS-type solar battery having high conversion, efficiency even at low illuminance.

### Solution to the Problems

In order to solve the aforementioned problems and achieve the purpose, a compound semiconductor solar battery according to the present invention includes a substrate; a back electrode disposed on the substrate; a p-type compound semiconductor light absorbing layer disposed on the back electrode; an n-type compound semiconductor buffer layer disposed on the p-type compound semiconductor light absorbing layer; and a transparent electrode disposed on the n-type compound semiconductor buffer layer. The p-type compound semiconductor light absorbing layer comprises Cuₐ (In_{1-y}Ga_{y}) Se₂, where 0≦y≦1 and 0.5≦a≦1.5. The p-type compound semiconductor light absorbing layer has a cross sectional structure including, in a thickness direction, a portion only of a single particle and a portion of a plurality of piled particles. In the portion of a plurality of piled particles, the particles in contact with the back electrode nave a ratio y₁ of Ga/(In+Ga), and the particles in contact with the n-type compound semiconductor buffer layer have a ratio y₂ of Ga/(In+Ga), where y₁>y₂.

When a plurality of particles is present in the thickness direction of the p-type compound semiconductor light absorbing layer, and the ratio y₁ of Ga/(In+Ga) in the particles in contact with the hack electrode and the ratio y₂ of Ga/(In+Ga) in the particles in contact with the buffer layer are such that y₁>y₂, low illuminance characteristics can be improved without degrading high illuminance characteristics. It is believed that not only the conversion, efficiency at low illuminance is increased but also no decrease in conversion efficiency at high illuminance is observed because a large band gap structure can be formed on the hack electrode side, with increases in shunt resistance and the open-circuit voltage, while short-circuit current is not easily lowered.

Preferably, in the compound semiconductor solar battery according to the present invention, the p-type compound semiconductor light absorbing layer may have an average value yₐᵥₑ of Ga/(In+Ga) such that 0.3≦yₐᵥₑ≦0.80.

When the average value yₐᵥₑ of Ga/(In+Ga) in the p-type compound semiconductor light absorbing layer is 0.30≦yₐᵥₑ≦0.80, band gap optimization can be achieved, and the conversion efficiency at low illuminance can be increased.

Preferably, in the compound semiconductor solar battery according to the present invention, the back electrode may be in contact with the portion only of a single particle by 10 to 60% in the cross section.

In this way, sufficient shunt resistance can be obtained, and the conversion efficiency at low illuminance can be increased.

### EFFECTS OF THE INVENTION

The present invention, can provide a CIGS-type compound semiconductor solar battery having high conversion efficiency even at low illuminance.

### BRIEF DESCRIPTION OF THE DRAWINGS

FIG. 1 is a schematic cross sectional view of a general compound semiconductor solar battery.

FIG. 2 is a cross sectional view of a compound semiconductor solar battery according to an embodiment of the present invention.

FIG. 3 is a cross sectional SEM image of a p-type compound semiconductor light absorbing layer according to Comparative Example 1.

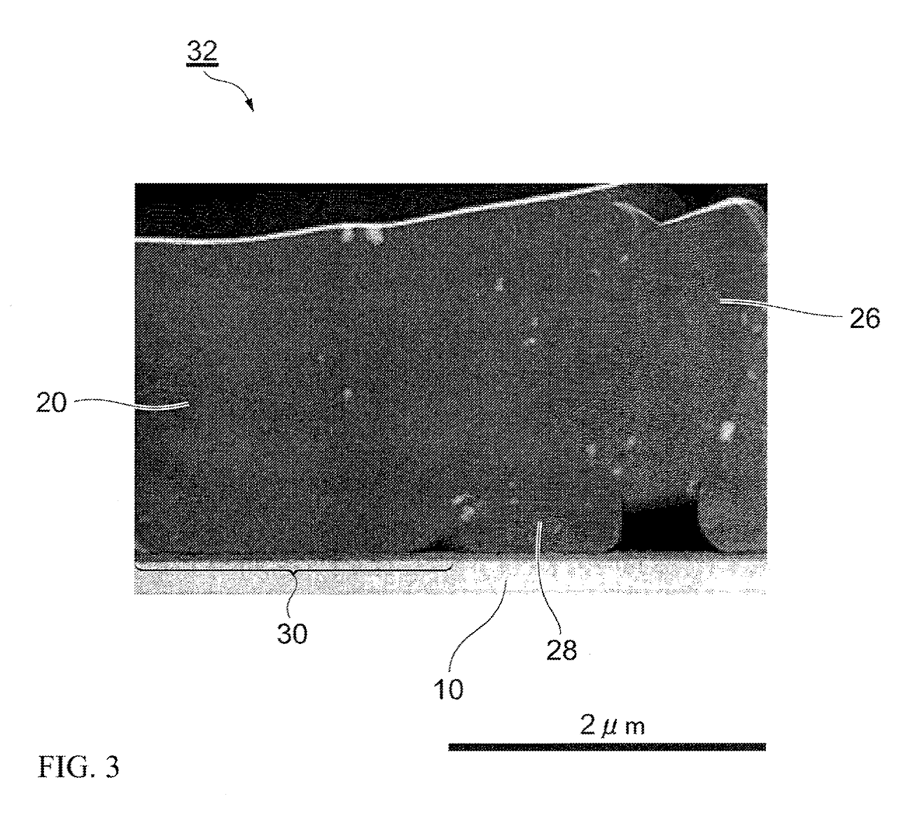

### MODE FOR CARRYING OUT THE INVENTION

In the following, a preferred embodiment of the present invention will be described with reference to the drawings. In the drawings, similar or equivalent elements are designated with similar signs. The upper-lower and left-right positional relationships are as shown in the drawings. Redundant descriptions will be omitted.

### (Compound Semiconductor Solar Battery)

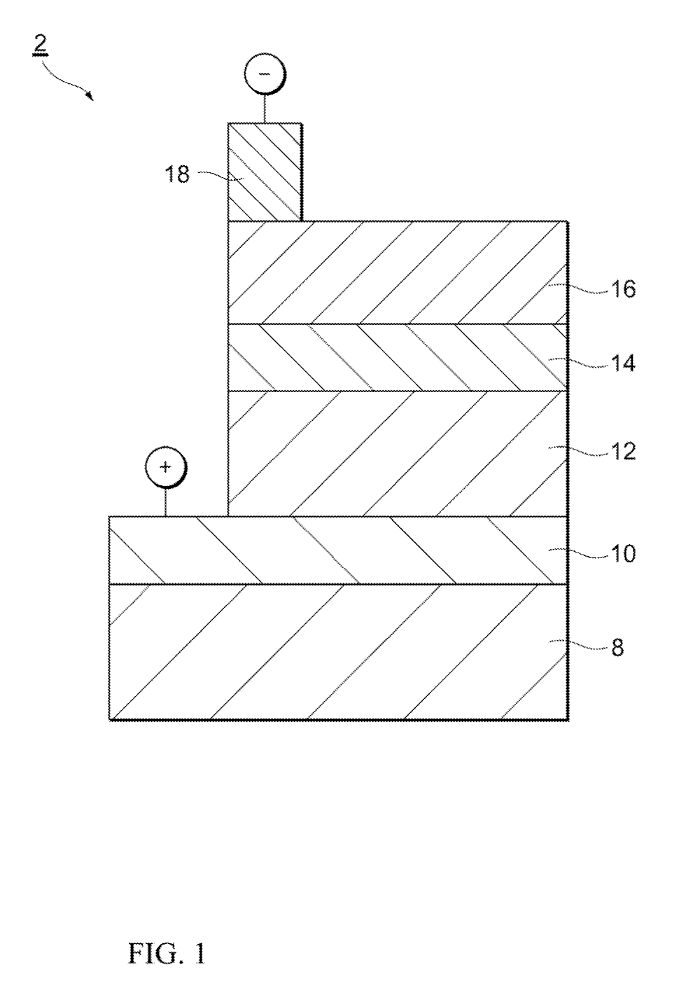

As shown in FIG. 1, a compound semiconductor solar battery 2 according to the present embodiment is a thin film type solar battery provided with a substrate 8; a back electrode 10 disposed on the substrate 8; a p-type compound semiconductor light absorbing layer 12 disposed on the back electrode 10; an n-type compound semiconductor buffer layer 14 disposed on the p-type compound semiconductor light absorbing layer 12; a transparent electrode 16 disposed on the n-type compound semiconductor buffer layer 14; and an upper electrode 18 disposed on the transparent electrode 16.

The substrate 8 is a support member for forming a thin film thereon, and may comprise a conductor or non-conductor as long as the substrate has a strength for sufficiently holding the thin film. For example, various materials used mainly in other compound semiconductor solar batteries may be used. Specifically, soda lime glass, quartz glass, non-alkaline glass, metals, semiconductors, carbon, oxides, nitrides, silicides, carbides, or resins such as polyimide may be used.

The back electrode 10 is disposed on the substrate 8 to collect current generated by the p-type compound semiconductor light absorbing layer 12. The back electrode 10 preferably has high electric conductivity and good adhesion with the substrate 4. For example, when soda lime glass is used for the substrate 8, Mo, MoS₂, or MoSe₂ may be used for the back electrode 10.

The p-type compound semiconductor light absorbing layer 12 produces a carrier by light absorption. The p-type compound semiconductor light absorbing layer comprises

Cuₐ(In_{1-y}Ga_{y})Se₂

where 0≦y≦1, and 0.5≦a≦1.5.

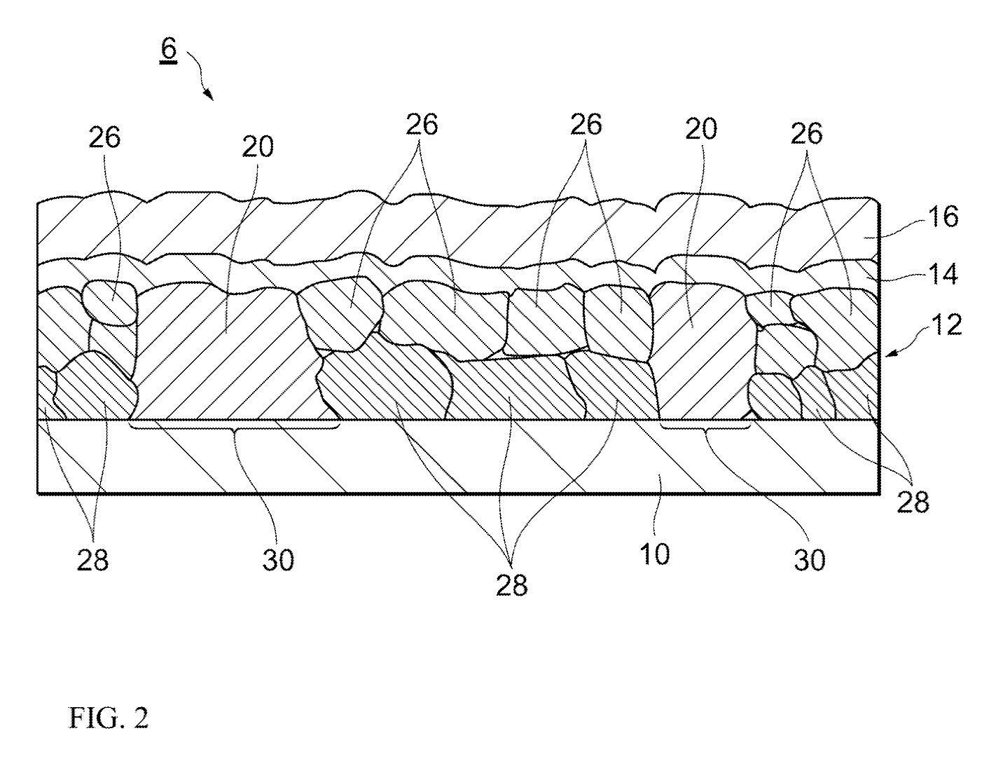

The p-type compound semiconductor light absorbing layer has a cross sectional structure including, in a thickness direction, a portion of only a single particle 20 and a portion of a plurality of piled particles. In the portion of the plurality of piled particles, a ratio y₁ of Ga/(In+Ga) of particles 28 in contact with the back electrode 10, and a ratio y₂ of Ga/(In+Ga) of panicles 26 in contact with the n-type compound semiconductor boiler layer are such that y₁>y₂ (refer to FIG. 2).

Thus, a plural ivy of particles is. present in the thickness direction of the p-type compound semiconductor light absorbing layer, and the ratio y₁ of Ga/(In+Ga) in the particles 28 in contact with the back electrode 10, and the ratio y₂ of Ga/(In+Ga) in the particles 26 in contact with the buffer layer are such that y₁>y₂. In this way, formation of a highly conductive heterogenous phase between the single particles across the p-type compound semiconductor light absorbing layer can be suppressed, and a pseudo-gradient structure of Ga concentration can be obtained, whereby the low illuminance characteristics can be improved without degrading the high illuminance characteristics.

Preferably, the p-type compound semiconductor light absorbing layer has an average value yₐᵥₑ of Ga/(In+Ga) such that 0.30≦yₐᵥₑ≦0.80.

When the average value yₐᵥₑ of Ga/(In+Ga) of the p-type compound semiconductor light absorbing layer is such that 0.30≦yₐᵥₑ≦0.80, band gap optimization can be achieved and conversion efficiency at low illuminance can be can be increased.

When portions 30 in which the back electrode 10 is in contact with the portions only of a single particle of the p-type compound semiconductor light absorbing layer in the cross section is 10 to 60%, sufficient shunt resistance can be obtained and the conversion efficiency at low illuminance can be increased.

The n-type compound semiconductor buffer layer 14 disposed on the p-type compound semiconductor light absorbing layer 12 needs to have a sufficiently wider band gap (low light absorption) than the p-type compound semiconductor light absorbing layer 12. Damage to the p-type compound semiconductor light absorbing layer 12 during formation of a film for the transparent electrode 16 by sputtering, for example, needs to be reduced. It is also required to bring the Fermi level at the interface of the p-type compound semiconductor Sight absorbing layer 12 and the n-type compound semiconductor buffer layer 14 closer to the conduction bund of the p-type compound semiconductor light absorbing layer 12.

Example materials that may be used tor the n-type compound semiconductor buffer layer 14 include CdS, ZnO, Zn (O, OH), Zn (O, S), Zn (O, S, OH), Zn₁₋ₓMgₓO, and In₂S₃.

For the transparent electrode 16 disposed on the n-type compound semiconductor buffer layer 14, an n-type ZnO containing a few percent of Al, Ga, or B may be used. As another example, a material with low resistance and having a high transmittance from visible light to near-infrared, such as indium tin oxide, may be used.

The upper electrode 18 disposed on the transparent electrode 16 has a comb-shaped configuration for efficient current collection. As the material of the upper electrode 18, Al may be used. A thin two-layer structure of Ni and Al may be adopted, or an Al alloy may be used.

Between the n-type compound semiconductor buffer layer 14 and the transparent electrode 16, a high resistance layer may be provided. For the high resistance layer, non-doped high-resistance ZnO or ZnMgO may be used.

On the insulating substrate 8, the back electrode 10 separated into a plurality of portions by insulating regions is provided, with a portion of the back electrode 10 exposed. On the back electrode 10 portions arranged side by side, the p-type compound semiconductor light absorbing layer 12 and the n-type compound semiconductor buffer layer 14 are successively provided while being offset toward one side of the back electrode 10 portions and across the electrode portions. Further, on the n-type compound semiconductor buffer layer 14, the transparent electrode layer 16 is provided, with the transparent electrode 16 connected to the back electrode 10 at the portion where the back electrode 10 is exposed. The transparent electrode 16 is insulated on the opposite portion to the insulating region on the substrate 8 with respect to the connected portion, and the plurality of separated solar battery cells is connected in series in an integrated structure, thus providing a solar battery module.

In this case, the upper electrode 18 may not be used.

In order to increase the rate of light absorption, a light scattering layer of, e.g., SiO₂, TiO₂, or Si₃N₄, or a reflection prevention layer of e.g., MgF₂ or Sio₂ may be disposed on top of the transparent electrode 16.

In order to obtain even higher conversion efficiency, the compound semiconductor solar battery of the present invention may be used as solar battery cells constituting a tandem type solar battery connecting a plurality of solar battery cells for absorbing light of different wavelength regions.

### (Method of Manufacturing Compound Semiconductor Solar Battery)

According to a method of manufacturing the compound semiconductor solar battery of the present embodiment, first the substrate 8 is prepared, and the back electrode 10 is formed on the substrate 8. For the back electrode 10, Mo may be used. The back electrode 10 may be formed by sputtering of an Mo target, for example.

After the back electrode 10 is formed on the substrate 8, the p-type compound semiconductor light absorbing layer 12 is formed on the back electrode 10. The p-type compound semiconductor light absorbing layer 12 may be formed by simultaneous vacuum vapor deposition, or by sulfurization/selenization process by which precursors are formed by sputtering, electrolytic deposition, coating, or printing, and then sulfurized/selenized.

In a chemical formula Cuₐ(In_{1-y}Ga_{y})Se₂,

where 0≦y≦1, and 0.5≦a≦1.5,

the p-type compound semiconductor light absorbing layer 12 has the cross sectional structure in the thickness direction including the portion only of the single particle 20 and the portion of a plurality of piled particles. Vapor deposition conditions, precursor creation conditions, and sulfurization/selenization conditions are adjusted such that in the portion of a plurality of piled particles, the ratio y₁ of Ga/(In+Ga) in the particles 28 in contact with the back electrode 10 and the ratio y₂ of Ga/(In+Ga) in the particles 26 in contact with the n-type compound semiconductor buffer layer 14 are such that y₁>y₂. In the case of vapor deposition, during multi-stage simultaneous vapor deposition, the substrate temperature and the flux of the vapor deposition source in each stop may be controlled for the adjustment. At the time of vapor deposition, precursors of In and Ga may be used in combination, whereby the portion of the plurality of piled particles may be more readily controlled. In the case of sulfurization/selenization process, precursor structures are layered while controlling the thickness of each of the layers of Cu, Ga, In, and Ga, and the sulfurization/selenization temperature may be controlled for the adjustment.

When In and Ga precursors are used in combination during vapor deposition, preferably an In film is formed on the back electrode 10 first, and then a Ga film is formed thereon. In this case, preferably the Ga film is formed by electrolytic deposition using an ion liquid as a solvent. Preferably, the In and Ga precursors have an overall precursor him composition such that Ga/In>1, and preferably the thickness of the Ga film as determined from the amount of energization is 20 nm or less.

In order to obtain higher conversion efficiency by band gap optimization, it is preferable to adjust the film, formation conditions such that the average value yₐᵥₑ of Ga/(In+Ga) in the p-type compound semiconductor light absorbing layer 12 is 0.30≦yₐᵥₑ≦0.80.

In order to obtain sufficient shunt resistance and increase the conversion efficiency at low illuminance, it is preferable that the portion 30 where the back electrode 10 and the portions of the p-type compound semiconductor light absorbing layer 12 of only the single particle are in contact in the cross section is 10 to 60%.

The cross section refers to a cross section such that the interface of the p-type compound semiconductor light absorbing layer 12 and the back electrode 10 is exposed, and may include a section cut by a cutter or a fracture surface.

Prior to the formation of the n-type compound semiconductor buffer layer 14, a surface of the p-type compound semiconductor light absorbing layer 12 may be etched by, e.g., a KCN solution. By extending the etching time, the composition of the p-type compound semiconductor light absorbing layer 12 can be provided with a gradient. The gradient in the composition of the p-type compound semiconductor light absorbing layer 12 may be provided by performing simultaneous vacuum vapor deposition in multiple stages.

After the p-type compound semiconductor light absorbing layer 12 is formed, the n-type compound semiconductor butler layer 14 is formed on the p-type compound semiconductor light absorbing layer 12. Exemplary materials include CdS or In₂S₃ containing Sn and Ge, ZnO, Zn (O, OH), Zn₁₋ₓMgₓO, Zn (O, S), and Zn (O, S, OH). To these, any of Ag and Co, Zn, or S and Se may be added.

The buffer layer may be formed by solution growth process, chemical vapor deposition such as metal organic chemical vapor deposition (MOCVD), sputtering, or atomic layer deposition (ALD) process.

By the solution growth process, a CdS layer containing Sn and Ge, a Zn (O, S, OH) layer, and the like can be formed. For example, in the case of CdS layer, a solution is prepared using a solution with Cd salt dissolved therein and an ammonium chloride (NH₄Cl) aqueous solution. The prepared solution is preferably heated to 40-80° C., and the p-type compound semiconductor light absorbing layer 12 is immersed in the solution for preferably 1 to 10 minutes. Thereafter, a thiourea (CH₄N₂S) aqueous solution made bask with the addition of ammonia water, preferably heated to 40-80° C., is added while stirring. After stirring for preferably 2 to 20 minutes, the p-type compound semiconductor light absorbing layer 12 is taken out of the solution, washed with, water, and then dried, thereby obtaining the buffer layer.

By MOCVD, a ZnMgO layer and the like can be formed. In the case of MOCVD, the layer may be obtained by forming a film using organic metal gas sources of Zn and Mg as material. By the ALD process, a Zn (O, S) layer and the like can be formed. In the case of ALD, too, as in the case of MOCVD, the layer may be obtained by forming a film by adjusting organic metal gas sources.

After the n-type compound semiconductor buffer layer 14 is formed, the transparent electrode 16 is formed on the n-type compound semiconductor buffer layer 14, and the upper electrode 18 is formed on the transparent electrode 16.

For the transparent electrode 16, n-type ZnO with an Al, Ga, or B content of several percent, or indium tin oxide may be used. The electrode may be formed by sputtering or chemical vapor deposition such as MOCVD.

The upper electrode 18 comprises a metal, such as Al or Ni. The upper electrode 18 may be formed by resistive heating vapor deposition, electronic beam vapor deposition or sputtering. In this way, the compound semiconductor solar battery 2 is obtained. On the transparent electrode 16, there may be formed a light scattering layer or a reflection prevention layer of, e.g., MgF₂, TiO₂, or SiO₂. The light scattering layer or the reflection prevention layer may be formed by resistive beating vapor deposition, electronic beam vapor deposition, or sputtering.

The back electrode 10 formed on the insulating substrate 8 is separated into a plurality of portions by scribing, followed by formation of films for the p-type compound semiconductor light absorbing layer 12, the n-type compound semiconductor buffer layer 14, and the high resistance layer thereon. The back electrode 10 is scribed slightly off the scribed portion, thus partially exposing the back electrode 10. The film for the transparent electrode 16 is formed thereon and scribed slightly off the earlier scribed portion, thus exposing the back electrode 10. Individual solar battery cells are separated, and a plurality of the solar battery cells is connected in series between the transparent electrode 12 and the back electrode 10 in an integrated structure. Lead electrodes are formed on both the back electrode 10 side and the transparent electrode 16 side, and cover glass and frame attachment and the like are implemented, thus producing an electrode solar battery module. In this case, the upper electrode 18 may not be used.

A tandem type solar battery may be formed by connecting the compound semiconductor solar battery cells and a plurality of solar battery cells including the p-type compound semiconductor light absorbing layers having different band gaps.

While a preferred embodiment of the present invention has been described, the present invention is not limited to the embodiment.

### EXAMPLES

### Example 1

On a soda lime glass substrate measuring 2.5 cm×2.5 cm, a Mo layer was formed to a thickness of 1 μm by sputtering.

(film Formation for P-Type Compound Semiconductor Light Absorbing Layer)

### (Electrolytic Deposition of In Layer)

InCl₃ was dissolved in an ion liquid (1-buthyl-1-methylpyrrolodium bis(trifuluoromethylsulfonyl)imide) to provide an electrolytic solution. The electrolytic solution had a concentration of [In]/[IL]=0.01, where [IL] is the number of moles of the ion liquid, and [In] is the number of moles of indium. Using the electrolytic solution, 10 nm of an In film was formed on the Mo layer by electrolytic deposition. As the counter electrode for electrolytic deposition, a Pt plate was used, and for the reference electrode, an Ag linear nonaqueous solvent electrode was used, with the cathode-anode electrodes distance of 1.5 cm and at room temperature. The potential of the cathode with respect to the reference electrode was −1.95 V, and the amount of energization was 28 mC. Thereafter, washing and drying were performed.

### (Electrolytic Deposition of Ga Layer)

GaCl₃ was dissolved in an ion liquid (1-buthyl-1-methylpyrrolidium bis(trifuluoromethylsulfonyl)imide) to provide an electrolytic solution. The electrolytic solution had a concentration of [Ga]/[IL]=0.01, where [IL] is the number of moles of the Ion liquid and [Ga] is the number of moles of gallium. Using the electrolytic solution, 12 nm of a Ga film was formed on the In layer by electrolytic deposition. As the counter electrode for electrolytic deposition, a Pt plate was used, and for the reference electrode, an Ag linear nonaqueous solvent electrode was used. The cathode-anode electrodes distance was 1.5 cm, the temperature was room temperature, the cathode potential with respect to the reference electrode was −2.10 V, and the amount of energization was 28 mC. Thereafter, washing and drying were performed. The resultant In—Ga layer was used as the substrate for forming the p-type compound semiconductor light absorbing layer.

### (Formation of P-Type Compound Semiconductor Light Absorbing Layer by Vapor Deposition)

Film formation for the p-type compound semiconductor light absorbing layer was performed in a physical vapor deposition (PVD) apparatus using three stages of vapor deposition conditions. The three stages included the first stage of In, Ga, and Se vapor deposition; the second stage of Cu and Se vapor deposition; and the third stage of In, Ga, and Se vapor deposition. Prior to the start of film formation, temperature settings of K-cells as vapor deposition sources were made so that the flux of each of the desired elements could be obtained, and the temperature-flux relationship was measured. Thus, the fluxes can be set to desired values as needed during film formation.

The flux for the first stage was as follows.

In: 5.33×10⁻⁵ Pa

Ga: 1.20×10⁻⁵ Pa

Se: 6.67×10⁻⁴ Pa

The flux for the second stage was as follows.

Cu: 1.33×10⁻⁵ Pa

Se: 6.67×10⁻⁴ Pa

The flux for the third stage was as follows.

In: 6.67×10⁻⁵ Pa

Ga: 1.07×10⁻⁵ Pa

Se: 6.67×10⁻⁴ Pa

The substrate with the In—Ga layer film formed in the ion liquid was installed in a chamber of the PVD apparatus, and the interior of the chamber was degassed. The pressure reached in the vacuum apparatus was 1.0×10⁻⁶ Pa.

In the first stage, the substrate was heated to 300° C., the shatters of the K-cells for In, Ga and Se were opened, and In, Ga and Se were vapor-deposited on the back electrode. At the point in time that a layer of a thickness of approximately 1 μm was formed on the back electrode by the vapor deposition, the shutters of the K-cells for in and Ga were closed, thus ending the In and Ga vapor deposition. Supply of Se was continued. After the first stage ended, the temperatures of the K-cells for In and Ga were modified so that the flux for the third stage can be reached.

In the second stage, after the substrate was heated to 520° C., the shutter of the K-cell for Cu was opened, and Cu was vapor-deposited on the back electrode together with Se. In the second stage, the surface temperature of the substrate was monitored with a radiation thermometer. Upon confirming that the temperature increase of the substrate stopped and a temperature decrease started, the shutter of the K-cell for Cu was closed, thus ending the Cu vapor deposition, while supply of Se was continued. At the point in time of the end of the second stage vapor deposition, compared with the point in time of the end of the first stage vapor deposition, the thickness of the layer formed on the back electrode was increased by approximately 0.8 μm.

In the third stage, the shutters of the K-cells for In and Ga were again opened, and, as in the first stage, In, Ga and Se were vapor-deposited on the back electrode. At the point in time when the thickness of the layer formed on the back electrode was increased by approximately 0.2 μm from the point in time of the start of the third stage vapor deposition, the shutters of the K-cells for In and Ga were closed, thus ending the third stage vapor deposition. Thereafter, after the substrate was cooled to 300° C., the shatter of the K-cell for Se was closed, thus ending the film formation for the p-type compound semiconductor light absorbing layer.

### (Buffer Layer Film Formation)

A mixture was prepared by mixing 72.5 parts by mass of distilled water, 6.5 parts by mass of 0.4 M cadmium chloride (CdCl₂) aqueous solution, and 21.0 parts by mass of 0.4 M ammonium chloride (NH₄Cl) aqueous solution. The mixture was heated to 60° C. and a resultant CIGS film was immersed in a 5 wt % KCN solution for 5 seconds, rinsed with water, dried, and then immersed in the mixture for 5 minutes. Thereafter, a mix tare was prepared by mixing 80 parts by mass of 0.8 M thiourea (CH₄N₂S) aqueous solution and 20 parts by mass of 13.8 M ammonia water, heated to 60° C., and poured while stirring. After stirring for 4 minutes, the CIGS film was taken out of the solution. The resultant CdS buffer layer had a thickness of 50 nm.

### (Transparent Electrode Film Formation)

In an RF sputtering apparatus, initially using a non-doped ZnO target, film formation was performed at 1.5 Pa and 400 W for 5 minutes, forming a ZnO transparent film having high resistance. Thereafter, using a ZnO target containing 2 wt % of Al, film formation was performed at 0.2 Pa and 200 W for 40 minutes, obtaining an Al-doped ZnO transparent electrode on the CIGS/CdS. The resultant Hint had a thickness of 600 nm.

### (Ni/Al Surface Electrode)

Using a comb-like mask in a vapor deposition apparatus, film formation was performed for 100 nm of Ni and 1 μm of Al surface electrodes. Then, the CIGS layer and above were sectioned into 1 cm×1 cm areas fry mechanical scribing, obtaining solar battery cells with 1 cm² areas.

### (Cross Sectional Observation by Scanning Electronic Microscope (SEM), and Energy Dispersive X-ray Spectrometry (EDS) Measurement)

In a cross section of the p-type compound semiconductor light absorbing layer, the presence of the portions only of a single particle and the portions of a plurality of piled particles in the thickness direction was confirmed by cross sectional observation by SEM. In the portion of a plurality of piled particles, the ratio y₁ of Ga/(In+Ga) in the particles in contact with the hack electrode, and the ratio y₂ of Ga/(In+Ga) in the particles in contact with the n-type compound semiconductor bailer layer were determined. Because the CIGS particles growth is isotropic in a plane parallel with the hack electrode, the determination of the ratio of contact between the CIGS particles and the back electrode may be substituted by an evaluation of the cross sectional state. The observation range was 50 μm, and the ratios y₁, y₂ were determined from the results of EDS of Ga and In in the particles in contact with the back electrode and in the particles in contact with the buffer layer. As a result, y₁=0.41 and y₂=0.33, and thus y₁>y₂. The average value yₐᵥₑ of Ga/(In+Ga) in the p-type compound semiconductor light absorbing layer was determined from the result of EDS of Ga and In in a region including all of thickness directions in the cross section of the p-type compound semiconductor light absorbing layer. As a result, yₐᵥₑ=0.37. The portions only of a single panicle in the cross section were determined in the observation range of 50 μm. As a result, the portions were 56%.

### (Solar Battery Characteristics)

Using a pseudo-solar light source (solar simulator) having a xenon lamp as a light source under the condition of 100 mW/cm² (AM 1.5) and simulating the solar light spectrum, I-V measurement was performed at high illuminance and conversion efficiency was computed. As a result, the conversion efficiency was 14.9%. Meanwhile, I-V measurement at low illuminance was performed under the condition of 0.15/cm² representing the indoor illuminance, and conversion efficiency was computed. As a result, the efficiency was 8.2%.

### Comparative Example 1

Comparative Example 1 was similar to Example 1 with the exception of the film formation method for the p-type compound semiconduuctor light absorbing layer.

### (Film Formation for the P-Type Compound Semiconductor Light Absorbing Layer)

Film formation was performed En the same way as in Example 1 with the exception that the flux, in the first stage of the three stages of vapor deposition conditions comprised

In: 6.67×10⁻⁵ Pa

Ga: 1.07×10⁻⁵ Pa

Se: 6.67×10⁻⁴ Pa.

### (Cross Sectional Observation by SEM and EDS Measurement)

In a cross section of the p-type compound semiconductor light absorbing layer, cross sectional observation by SEM only identified the portions only of a single particle in the thickness direction. The average value yₐᵥₑ of Ga/(In+Ga) in the p-type compound semiconductor light absorbing layer was yₐᵥₑ=0.29. The portions only of a single particle in the cross section were 100%.

### (Solar Battery Characteristics)

As in Example 1, I-V measurement at high illuminance was performed and conversion efficiency was computed. As a result, the conversion efficiency was 15.1%. As in Example 1, I-V measurement at low illuminance was performed and conversion efficiency was computed. As a result, the conversion efficiency was 0.8%.

### Example 2

Example 2 was similar to Example 1 with the exception of the film formation method for the p-type compound semiconductor light absorbing layer.

### (Film Formation for the P-Type Compound Semiconductor Light Absorbing Layer)

### (Electrolytic Deposition of In Layer)

The deposition was performed as in Example 1 with the exception that the amount of energization was 18 mC and the In layer had a film thickness of 6.4 nm.

### (Electrolytic Deposition of Ga Layer)

The deposition was performed as in Example 1. The resultant In—Ga layer was used as the substrate for forming the p-type compound semiconductor light absorbing layer.

### (Formation of P-Type Compound Semiconductor Light Absorbing Layer by Vapor Deposition)

The formation was performed as in Example 1 with the exception that:

the flux in the first stage of the three stages of vapor deposition conditions comprised

In: 4.00×10⁻⁵ Pa

Ga: 1.33×10⁻⁵ Pa

Se: 6.67×10⁻⁴ Pa; and

the flux tor the third stage comprised

In: 5.33×10⁻⁵ Pa

Ga: 1.20×10⁻⁵ Pa

Se: 6.67×10⁻⁴ Pa.

### (Cross Sectional Observation by SEM and EDS Measurement)

When y₁=0.56 and y₂=0.43, y₁ was greater than y₂. The average value yₐᵥₑ of Ga/(In+Ga) in the p-type compound semiconductor light absorbing layer was determined from the result of EDS of Ga and In in a region including all of thickness directions in the cross section of the p-type compound semiconductor light absorbing layer. As a result, yₐᵥₑ=0.49. The portions only of a single particle in the cross section were 38%.

### (Solar Battery Characteristics)

As in Example 1, I-V measurement at high illuminance was performed and conversion efficiency was computed. As a result, the conversion efficiency was 14.8%. Further, as in Example 1, 1-V measurement at low illuminance was performed and conversion, efficiency was computed. As a result, the conversion efficiency was 9.5%.

### Example 3

Example 3 was similar to Example 1 with the exception of the film formation method for the p-type compound semiconductor light absorbing layer.

### (Film Formation for P-Type Compound Semiconductor Light Absorbing Layer)

### (Electrolytic Deposition of In Layer)

The deposition was performed as in Example 1 with the exception that the amount of energization was 4.7 mC and that the In layer had a film thickness of 1.7 nm.

### (Electrolytic Deposition of Ga Layer)

The deposition was performed as in Example 1. The resultant In—Ga layer was used as the substrate for forming, the p-type compound semiconductor light absorbing layer.

### (Formation of P-Type Compound Semiconductor Light Absorbing Layer by Vapor Deposition)

The formation was performed as in Example 1 with the exception that:

the flux in the first stage of the three stages of vapor deposition conditions comprised

In: 2.67×10⁻⁵ Pa

Ga: 1.47×10⁻⁵ Pa

Se: 6.67×10⁻⁴ Pa; and

the flux for the third stage comprised

In: 4.00×10⁻⁵ Pa

Ga: 1.33×10⁻⁵ Pa

Se: 6.67×10⁻⁴ Pa.

### (Cross Sectional Observation by SEM and EDS Measurement)

When y₁=0.72 and y₂=0.55, y₁ was greater than y₂. The average value yₐᵥₑ of Ga/(In+Ga) in the p-type compound semiconductor light absorbing layer was determined from the result of EDS of Ga and In in a region including all of thickness directions in the cross section of the p-type compound semiconductor light absorbing layer. As a result, yₐᵥₑ was 0.64. The portions only of a single particle in the cross section were 11%.

### (Solar Battery Characteristics)

As in Example 1, I-V measurement at high illuminance was performed and conversion efficiency was computed. As a result, the conversion efficiency was 14.0%. Further, as in Example 1, I-V measurement at low illuminance was performed and conversion, efficiency was computed. As a result, conversion efficiency was 9.4%.

### Comparative Example 2

Comparative Example 2 was similar to Example 1 with the exception of the film formation method for the p-type compound semiconductor light absorbing layer.

### (Film Formation for the P-Type Compound Semiconductor Light Absorbing Layer)

Film formation, was performed as in Example 1 with the exception that:

the flux in the first stage of the three stages of vapor deposition conditions comprised

In: 1.33×10⁻⁵ Pa

Ga: 1.60×10⁻⁵ Pa

Se: 6.67×10⁻⁴ Pa; and

the flux for the third stage comprised

In: 1.33×10⁻⁵ Pa

Ga: 1.60×10⁻⁵ Pa

Se: 6.67×10⁻⁴ Pa.

### (Cross Sectional Observation by SEM and EDS Measurement)

When y₁=0.81 and y₂=0.81, y₁ was equal to y₂. The average value yₐᵥₑ of Ga/(In+Ga) in the p-type compound semi conductor light absorbing layer was determined from the result of EDS of Ga and In in a region including all of thickness directions in the cross section of the p-type compound semiconductor light absorbing layer. As a result, yₐᵥₑ was 0.81. The portions only of a single particle in the cross section were 0%.

### (Solar Battery Characteristics)

As In Example 1, I-V measurement at high illuminance was performed and conversion efficiency was computed. As a result, the conversion efficiency was 8.0%. Further, as in Example 1, I-V measurement at low illuminance was performed and conversion efficiency was computed. As a result, the conversion efficiency was 5.6%.

Table 1 shows the results of the above examples.

TABLE 1

| | | | | | Ratio of single particles | Conversion efficiency/% | |
|---|---|---|---|---|---|---|---|
| | a | y₁ | y₂ | yₐᵥₑ | contacting back electrode | 100 mW/cm² | 0.15 mW/cm² |
| Comp. Ex. 1 | 0.98 | — | — | 0.29 | 100% | 15.1 | 0.8 |
| Example 1 | 0.98 | 0.41 | 0.33 | 0.37 | 58% | 14.9 | 8.2 |
| Example 2 | 0.96 | 0.56 | 0.43 | 0.49 | 38% | 14.8 | 9.5 |
| Example 3 | 0.93 | 0.72 | 0.55 | 0.64 | 11% | 14 | 9.4 |
| Comp. Ex. 2 | 9.96 | 0.81 | 0.81 | 0.81 | 0% | 8 | 5.6 |

### Example 4

Example 4 was similar to Example 1 with the exception of the film formation method for the p-type compound semiconductor light absorbing layer.

### (Film Formation for the P-Type Compound Semiconductor Light Absorbing Layer)

### (Electrolytic Deposition of In Layer)

The deposition was performed in the same way as in Example 2.

### (Electrolytic Deposition of Ga Layer)

The deposition was performed in the same way as in Example 2. The resultant In—Ga layer was used as the substrate tor forming the p-type compound semiconductor light absorbing layer.

### (Formation of P-Type Compound Semiconductor Light Absorbing Layer by Vapor Deposition)

The formation was performed in the same way as in Example 2 with the exception that at the point in time of the end of the second stage vapor deposition of the three stages of vapor deposition conditions, compared with the point in time of the end of the first stage vapor deposition, the thickness of the layer formed on the hack electrode was increased by approximately 0.62 μm.

### (Cross Sectional Observation by SEM and EDS Measurement)

When y₁=0.55 and y₂=0.42, y₁ was greater than y₂. The average value yₐᵥₑ of Ga/(In+Ga) in the p-type compound semiconductor light absorbing layer was determined from the result of EDS of Ga and In in a region including all of thickness directions in the cross section of the p-type compound semiconductor light, absorbing layer. As a result, yₐᵥₑ was 0.47. The portions only of a single particle in the cross section were 24%.

### (Solar Battery Characteristics)

As in Example 1, I-V measurement at high illuminance was performed and conversion efficiency was computed. As a result, the conversion efficiency was 14.2%. Further, as in Example 1, I-V measurement at low illuminance was performed and conversion efficiency was computed. As a result, the conversion efficiency was 9.4%.

### Example 5

Example 5 was similar to Example 1 with the exception of the film formation method: tor the p-type compound semiconductor light absorbing layer.

### (Film Formation for the P-Type Compound Semiconductor Light Absorbing Layer)

### (Electrolytic Deposition of In Layer)

The deposition was performed in the same way as in Example 3.

### (Electrolytic Deposition of Ga Layer)

The deposition was performed in the same way as in Example 3. The resultant In—Ga layer was used as the substrate for forming the p-type compound semiconductor light absorbing layer.

### (Formation of P-Type Compound Semiconductor Light Absorbing Layer by Vapor Deposition)

The formation was performed in the same way as in Example 3 with the exception that:

the flux in the first stage of the three stages of vapor deposition conditions comprised

In: 1.97×10⁻⁵ Pa

Ga: 1.53×10⁻⁵ Pa

Se: 6.67×10⁻⁴ Pa;

at the point in time of the end of the second stage vapor deposition, compared with the point in time of the end of the first stage vapor deposition, the thickness of the layer formed on the back electrode was increased by approximately 0.86 μm; and
the flux for the third stage comprised

In: 6.67×10⁻⁵ Pa

Ga: 1.07×10⁻⁵ Pa

Se: 6.67×10⁻⁴ Pa.

### (Cross Sectional Observation by SEM and EDS Measurement)

When y₁=0.76 and y₂=0.33, y₁ was greater than y₂. The average value yₐᵥₑ of Ga/(In+Ga) in the p-type compound semiconductor light absorbing layer was determined from the result of EDS of Ga and In in a region including all of thickness directions in the cross section of the p-type compound semiconductor light absorbing layer. As a result, yₐᵥₑ was 0.55. The portions only of a single particle in the cross section were 12%.

### (Solar Battery Characteristics)

As in Example 1, I-V measurement at high illuminance was performed and conversion efficiency was computed. As a result, the conversion efficiency was 13.3%. Further, as in Example 1, I-V measurement at low illuminance was performed and conversion, efficiency was computed. As a result, the conversion efficiency was 9.2%.

### Example 6

Example 6 was similar to Example 1 with the exception of the film formation method for the p-type compound semiconductor light absorbing layer.

### (Film Formation for the P-Type Compound Semiconductor Light Absorbing Layer)

### (Electrolytic Deposition of In Layer)

The deposition was performed as in Example 1.

### (Electrolytic Deposition of Ga Layer)

The deposition was performed as in Example 1 with the exception that the temperature of the electrolytic deposition was 60° C. The resultant In—Ga layer was used as the substrate tor forming the p-type compound semiconductor light absorbing layer.

### (Formation of P-Type Compound Semiconductor Light Absorbing Layer by Vapor Deposition)

The formation was performed as in Example 1 with the exception that the flux in the first stage of the three stages of vapor deposition conditions comprised

In: 4.62×10⁻⁵ Pa

Ga: 1.26×10⁻⁵ Pa

Se: 6.67×10⁻⁴ Pa.

### (Cross Sectional Observation by SEM and EDS Measurement)

When y₁=0.49 and y₂=0.32, y₁ was greater than y₂. The average value yₐᵥₑ of Ga/(In+Ga) in the p-type compound semiconductor light absorbing layer was determined from the result of EDS of Ga and In in a region including all of thickness directions in the cross section of the p-type compound semiconductor light absorbing layer. As a result, yₐᵥₑ was 0.41. The portions only of a single particle in the cross section were 22%.

### (Solar Battery Characteristics)

As in Example 1, I-V measurement at high illuminance was performed, and conversion efficiency was computed. As a result, the conversion efficiency was 15.0%. Further, as in Example 1, I-V measurement at low illuminance was performed, and conversion efficiency was computed. As a result, the conversion efficiency was 9.0%.

### Example 7

Example 7 was similar to Example 1 with the exception of the film formation method for the p-type compound semiconductor light absorbing layer.

### (Film Formation for the P-type Compound Semiconductor Light Absorbing Layer)

### (Electrolytic Deposition of In Layer)

The deposition was performed in the same way as in Example 2.

### (Electrolytic Deposition of Ga Layer)

The deposition was performed in the same way as in Example 2 with the exception that the temperature of the electrolytic deposition was 60° C. The resultant In—Ga layer was used as the substrate for forming the p-type compound semiconductor light absorbing layer.

### (Formation of P-Type Compound Semiconductor Light Absorbing Layer by Vapor Deposition)

The formation was performed in the same way as in Example 2 with the exception That:

the flux in the first stage of the three stages of vapor deposition conditions comprised

In: 3.05×10⁻⁵ Pa

Ga: 1.48×10⁻⁵ Pa

Se: 6.67×10⁻⁴ Pa;

at the point in time of the end of the second stage vapor deposition, compared with the point in time of the end of the first stage vapor deposition, the thickness of the layer formed on the back electrode was increased by approximately 0.74 μm; and
the flux for the third stage comprised

In: 4.89×10⁻⁵ Pa

Ga: 1.29×10⁻⁵ Pa

Se: 6.67×10⁻⁴ Pa.

### (Cross Sectional Observation by SEM and EDS Measurement)

When y₁=0.69 and y₂=0.47, y₁ was greater than y₂. The average value yₐᵥₑ of Ga/(In+Ga) in the p-type compound semiconductor light absorbing layer was determined from the result of EDS of Ga and In in a region including all of thickness directions in the cross section of the p-type compound semiconductor light absorbing layer. As a result, yₐᵥₑ was 0.58. The portions only of a single particle in the cross section were 16%.

### (Solar Battery Characteristics)

As in Example 1, I-V measurement at high illuminance was performed, and conversion efficiency was computed. As a result, the conversion efficiency was 14.8%. Further, as in Example 1, I-V measurement at low illuminance was performed and conversion efficiency was computed. As a result, the conversion efficiency was 9.5%.

### Example 8

Example 8 was similar to Example 1 with the exception of the film formation method for the p-type compound semiconductor light absorbing layer.

### (Film Formation for the P-Type Compound Semiconductor Light Absorbing Layer)

### (Electrolytic Deposition of In Layer)

The deposition was performed in the same way as in Example 3.

### (Electrolytic Deposition of Ga Layer)

The deposition was performed in the same way as in Example 3 with the exception that the temperature of the electrolytic deposition was 60° C. The resultant In—Ga layer was used as the substrate for forming the p-type compound semiconductor light absorbing layer.

### (Formation of P-Type Compound Semiconductor Light Absorbing Layer by Vapor Deposition)

The formation was performed in the same way as in Example 3 with the exception that:

the flux in the first stage of the three stages of vapor deposition conditions comprised

In: 1.34×10⁻⁵ Pa

Ga: 1.66×10⁻⁵ Pa.

Se: 6.67×10⁻⁴ Pa;

at the point in time of the end of the second stage vapor deposition, compared, with the point in time of the end of the first stage vapor deposition, the thickness of the layer formed on the back electrode was increased by approximately 0.72 μm; and
the flux for the third stage comprised

In: 3.34×10⁻⁵ Pa

Ga: 1.40×10⁻⁵ Pa

Se: 6.67×10⁻⁴ Pa.

### (Cross Sectional Observation by SEM and EDS Measurement)

When y₁=0.89 and y₂=0.61. y₁ was greater than y₂. the average value yₐᵥₑ of Ga/(In+Ga) in the p-type compound semiconductor light absorbing layer was determined from the result of EDS of Ga and In in a region including all of thickness directions in the cross section of the p-type compound semiconductor light absorbing layer. As a result, yₐᵥₑ was 0.75. The portions only of a single particle in the cross section were 13%.

### (Solar Battery Characteristics)

As in Example 1, I-V measurement at high illuminance was performed and conversion efficiency was computed. As a result, the conversion efficiency was 12.8%. Further, as in Example 1, I-V measurement at low illuminance was performed and conversion efficiency was computed. As a result, the conversion efficiency was 8.3%.

Table 2 shows the results of the foregoing embodiments.

### [Table 2]

### DESCRIPTION OF REFERENCE SIGNS

2 Compound semiconductor solar battery
4 Conventional CIGS compound semiconductor solar battery
6 CIGS compound semiconductor solar battery
8 Substrate
10 Back electrode
12 p-type compound semiconductor light absorbing layer
14 n-type compound semiconductor buffer layer
16 Transparent electrode
18 Upper electrode
20 Portion only of single particle
26 Particles in contact with the back electrode in a piled portion
28 Particles in contact with the n-type compound semiconductor buffer layer in the piled portion
30 Portion where the back electrode and the portion only of a single particle of the p-type compound semiconductor light absorbing layer are in contact with each other in their cross section
32 Cross sectional SEM Image of p-type compound semiconductor light absorbing layer

1. A compound semiconductor solar battery comprising:
a substrate;
a back electrode disposed on the substrate;
a p-type compound semiconductor light absorbing layer disposed on the back electrode;
an n-type compound semiconductor buffer layer disposed on the p-type compound semiconductor light absorbing layer; and
a transparent electrode disposed on the n-type compound semiconductor buffer layer,
wherein:
the p-type compound semiconductor light absorbing layer comprises Cuₐ(In_{1-y}Ga_{y})Se₂, where 0≦y≦1 and 0.5≦a≦1.5;
the p-type compound semiconductor light absorbing layer has a cross sectional structure including, in a thickness direction, a portion only of a single particle and a portion of a plurality of piled particles; and
in the portion of a plurality of piled particles, the particles in contact with the back electrode have a ratio y₁ of Ga/(In+Ga), and the particles in contact with the n-type compound semiconductor buffer layer have a ratio y₂ of Ga/(In+Ga), where y₁>y₂.

2. The compound semiconductor solar battery according to claim 1, wherein the p-type compound semiconductor light absorbing layer has an average value yₐᵥₑ of Ga/(In+Ga) such that 0.30≦yₐᵥₑ≦0.80.

3. The compound semiconductor solar battery according to claim 1, wherein the back electrode is in contact with the portion only of a single particle by 10 to 60% in the cross section.

4. The compound semiconductor solar battery according to claim 2, wherein the back electrode is in contact with the portion only of a single particle by 10 to 60% in the cross section.
